(19) United States
(12) Patent Application Publication
(10) Pub. No.: US 2019/0217419 A1
(43) Pub. Date: Jul. 18, 2019

(54) METHOD OF PROCESSING WORKPIECE WITH LASER BEAM

(71) Applicant: DISCO CORPORATION, Tokyo (JP)

(72) Inventors: Naotoshi KIRIHARA, Tokyo (JP); Noboru TAKEDA, Tokyo (JP); Yukihiro KIRIBAYASHI, Tokyo (JP); Hiroshi MORIKAZU, Tokyo (JP); Taro ARAKAWA, Tokyo (JP)

(21) Appl. No.: 16/248,264

(22) Filed: Jan. 15, 2019

(30) Foreign Application Priority Data
Jan. 16, 2018 (JP) 2018-005053

(51) Int. Cl. B23K 26/364; H01L 21/8258; B23K 26/53; B23K 26/0622; H01L 21/304

(52) U.S. Cl. CPC B23K 26/364; H01L 21/8258; B23K 2101/40; B23K 26/0622; H01L 21/3043; B23K 26/53

(57) ABSTRACT

A method of processing a plate-shaped work-piece with a laser beam so as to be divided along a plurality of projected dicing lines on the workpiece includes: forming a plurality of first shield tunnels, each including fine pores and an amorphous substance surrounding the fine pores, in the workpiece along the projected dicing lines by applying a pulsed laser beam having a wavelength transmittable through the workpiece to the workpiece along the projected dicing lines while positioning a converged zone of the pulsed laser beam within the workpiece; changing the converged zone of the pulsed laser beam to be applied to the workpiece to a position along thicknesswise directions of the workpiece; and, forming a plurality of second shield tunnels in the workpiece adjacent and parallel to the first shield tunnels along the direction in which the pulsed laser bream is applied.

### BACKGROUND OF THE INVENTION

### Field of the Invention

The present invention relates to a method of processing a relatively thick plate-shaped workpiece such as a sheet of glass or the like with a laser beam.

### Description of the Related Art

Heretofore, cutting apparatus called dicing saws have been used to divide wafers into individual device chips. However, it is difficult for the dicing saws to cut hard brittle materials including sapphire, silicon carbide (SiC), and so on for substrates for crystalline growth, i.e., epitaxy substrates, such as optical device wafers or the like. In recent years, attention has been attracted to the technology for dividing wafers into a plurality of device chips with a laser beam using a laser processing apparatus.

One of laser processing methods that are performed using laser processing apparatus is a technology in which a pulsed laser beam having a wavelength that is transmittable through a wafer is applied to the wafer to form modified layers that have a reduced mechanical strength in the wafer, and external forces are then applied to the wafer along the modified layers by an expanding apparatus or the like, dividing the wafer into a plurality of device chips. The technology is disclosed in Japanese Patent Laid-open No. 2005-129607, for example.

According to the above laser processing method, also known as a Stealth Dicing (SD) process, in which a pulsed laser beam having a wavelength that is transmittable through a wafer is applied to the wafer to form modified layers therein, the pulsed laser beam has to be applied a plurality of times to each dicing line on the wafer. Consequently, there have been demands in the art for a further increase in productivity.

Japanese Patent No. 6151557 discloses a laser processing method whereby a pulsed laser beam having a wavelength that is transmittable through a wafer made of a single-silicon substrate such as a sapphire substrate, an SiC substrate, or the like is applied to the wafer through a condensing lens having a relatively small numerical aperture, intermittently linearly forming a plurality of shield tunnels each made up of fine pores and an amorphous substance that shields the fine pores in the substrate, and thereafter external forces are applied to the wafer to divide the wafer into individual device chips.

### SUMMARY OF THE INVENTION

According to the laser processing method disclosed in Japanese Patent No. 6151557, if the plate-shaped workpiece is thicker, then the shield tunnels are shorter compared to the thickness of the workpiece, with the result that it will be difficult or impossible to divide the workpiece into individual device chips.

It is therefore an object of the present invention to provide a method of processing a workpiece with a laser beam to efficiently divide the workpiece into individual device chips by keeping the workpiece well dividable or cleavable even if the workpiece is relatively thick.

In accordance with an aspect of the present invention, there is provided a method of processing a plate-shaped workpiece with a laser beam so as to be divided along a plurality of projected dicing lines on the workpiece, including: a first shield tunnel forming step of forming a plurality of first shield tunnels each including fine pores and an amorphous substance surrounding the fine pores, in the workpiece along the projected dicing lines by applying a pulsed laser beam having a wavelength transmittable through the workpiece to the workpiece along the projected dicing lines while positioning a converged zone of the pulsed laser beam within the workpiece; after the first shield tunnel forming step, a converged zone position changing step of changing the converged zone position of the pulsed laser beam to be applied to the workpiece to a position along thicknesswise directions of the workpiece; and after the converged zone position changing step, a second shield tunnel forming step of forming a plurality of second shield tunnels in the workpiece adjacent and parallel to the first shield tunnels along the direction in which the pulsed laser bream is applied, by applying the pulsed laser beam having a wavelength transmittable through the workpiece to the workpiece along the projected dicing lines while positioning the converged zone of the pulsed laser beam within the workpiece, in which the converged zone position changing step and the second shield tunnel forming step are repeated until a sum of a length of the first shield tunnels and a length of the second shield tunnels along the thicknesswise directions of the workpiece becomes substantially same as the thickness of the workpiece.

Preferably, the first shield tunnels formed in the workpiece have ends exposed on one of opposite surfaces of the workpiece. Preferably, the first shield tunnels and the second shield tunnels formed adjacent and parallel to each other in the workpiece along the thicknesswise directions of the workpiece overlap each other along the direction in which the pulsed laser bream is applied, by a distance in a range of ±20 μm.

According to the present invention, the method makes it possible to efficiently divide a relatively thick plate-shaped workpiece that cannot be divided or is hard to divide by the conventional method, and hence to increase the productivity of divided products from the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a block diagram schematically illustrating a laser beam applying unit according to a first embodiment of the present invention;

FIG. 2 is a block diagram schematically illustrating a laser beam applying unit according to a second embodiment of the present invention;

FIG. 3A is a diagram schematically illustrating a pulsed laser beam emitted from a laser oscillator of the laser beam applying unit according to the second embodiment;

FIG. 3B is a diagram schematically illustrating a pulsed laser beam that has passed through first thinning-out means of the laser beam applying unit according to the second embodiment;

FIG. 3C is a diagram schematically illustrating a pulsed laser beam that has been amplified by an amplifier of the laser beam applying unit according to the second embodiment;

FIG. 3D is a diagram schematically illustrating a burst pulsed laser beam that has been generated by second first thinning-out means of the laser beam applying unit according to the second embodiment;

FIG. 4 is a fragmentary perspective view of a laser processing apparatus suitable for performing first and second shield tunnel forming steps;

FIG. 5A is a side elevational view illustrating a shield tunnel forming step performed on a workpiece according to the first embodiment;

FIG. 5B is a side elevational view, partly in cross section, of the workpiece after the shield tunnel forming step according to the first embodiment has been performed thereon;

FIG. 6A is a schematic fragmentary cross-sectional view of the workpiece after a first shield tunnel forming step according to the first embodiment has been performed thereon to form shield tunnels in the workpiece from a lower surface thereof;

FIG. 6B is a schematic fragmentary cross-sectional view of the workpiece after a second shield tunnel forming step according to the first embodiment has been performed thereon;

FIG. 6C is a schematic fragmentary cross-sectional view of the workpiece after a third shield tunnel forming step according to the first embodiment has been performed thereon, i.e., after the second shield tunnel forming step according to the first embodiment has been repeated thereon;

FIG. 7A is a side elevational view illustrating a shield tunnel forming step performed on a workpiece according to the second embodiment;

FIG. 7B is a side elevational view, partly in cross section, of the workpiece after the shield tunnel forming step according to the second embodiment has been performed thereon;

FIG. 8A is a schematic fragmentary cross-sectional view of the workpiece after a first shield tunnel forming step according to the second embodiment has been performed thereon to form shield tunnels in the workpiece from an upper surface thereof;

FIG. 8B is a schematic fragmentary cross-sectional view of the workpiece after a second shield tunnel forming step according to the second embodiment has been performed thereon;

FIG. 8C is a schematic fragmentary cross-sectional view of the workpiece after a third shield tunnel forming step according to the second embodiment has been performed thereon, i.e., after the second shield tunnel forming step according to the second embodiment has been repeated thereon;

FIG. 9A is a schematic fragmentary cross-sectional view of the workpiece, illustrating an overlapping relationship between first and second shield tunnels in the workpiece;

FIG. 9B is an enlarged schematic fragmentary cross-sectional view of a portion P of the workpiece illustrated in FIG. 9A, where the first and second shield tunnels do not overlap each other, i.e., they are in a state defined as a negatively overlapping state; and

FIG. 9C is an enlarged schematic fragmentary cross-sectional view of another portion P of the workpiece illustrated in FIG. 9A, where the first and second shield tunnels overlap each other.

### DETAILED DESCRIPTION OF THE PREFERRED EMBODIMENTS

Like or corresponding parts are denoted by like or corresponding reference characters throughout views.

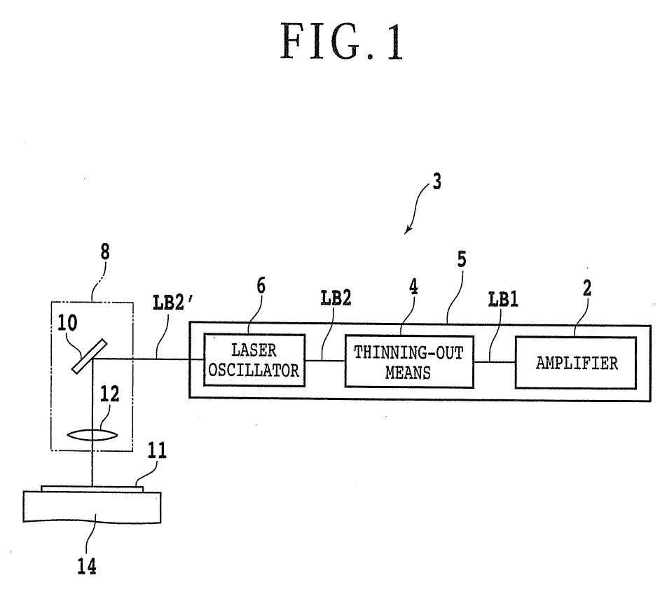

Methods of processing a workpiece with a laser beam, or laser processing methods, according to preferred embodiments of the present invention will be described in detail below with reference to the drawings. FIG. 1 illustrates in block form a laser beam applying unit 3 according to a first embodiment of the present invention. As illustrated in FIG. 1, the laser beam applying unit 3 includes a pulsed laser beam generating unit 5 for generating and emitting a pulsed laser beam and a beam condenser 8 for converging the pulsed laser beam emitted from the pulsed laser beam generating unit 5 and applying the converged pulsed laser beam to a plate-shaped workpiece 11 held on a chuck table 14.

The pulsed laser beam generating unit 5 includes a pulsed laser oscillator 2 such as YAG or YVO4 laser, for example, that oscillates and emits a pulsed laser beam LB1 having a wavelength of 1030 nm or 1064 nm, for example. The pulsed laser beam LB1 emitted from the pulsed laser oscillator 2 has a very high repetitive frequency of several tens MHz, for example.

The pulsed laser beam LB1 from the pulsed laser oscillator 2 is applied to thinning-out means 4. The thinning-out means 4 thins-out pulses of the pulsed laser beam LB1 at predetermined intervals, thereby converting the pulsed laser beam LB1 into a pulsed laser beam LB2 having a repetitive frequency ranging from 10 kHz to 50 kHz. The thinning-out means 4 may include an acousto-optical modulator (AOM) with a beam shuttering capability, for example.

The pulsed laser beam LB2 emitted from the thinning-out means 4 is applied to an amplifier 6 that amplifies the pulsed laser beam LB2 into a pulsed laser beam LB2′. The pulsed laser beam LB2′ is applied to the beam condenser 8. The beam condenser 8 includes a mirror 10 and a condensing lens 12.

In the beam condenser 8, the pulsed laser beam LB2′ amplified by the amplifier 6 is reflected by the mirror 10 to travel vertically to the condensing lens 12. Preferably, the condensing lens 12 should be a lens having a relatively small numerical aperture (NA) and a spherical aberration.

The plate-shaped workpiece 11 is a relatively thick workpiece having a thickness of 1 mm or larger. According to the present embodiment, a sheet of glass having a thickness of 3 mm is used as the plate-shaped workpiece 11. However, the workpiece 11 is not limited to a sheet of glass, but may be made of any materials insofar as they are relatively thick and able to transmit therethrough the pulsed laser beam emitted from the beam condenser 8.

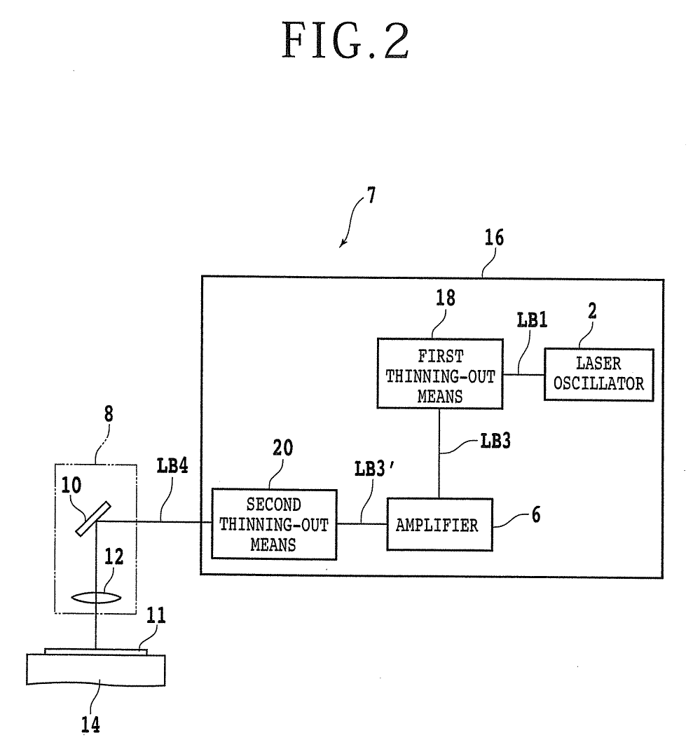

FIG. 2 illustrates in block form a laser beam applying unit 7 according to a second embodiment of the present invention. As illustrated in FIG. 2, the laser beam applying unit 7 includes a burst pulsed laser beam generating unit 16 and the beam condenser 8. The burst pulsed laser beam generating unit 16 includes the pulsed laser oscillator 2 such as YAG or YVO4 laser, that oscillates and emits a pulsed laser beam LB1 having a wavelength of 1030 nm or 1064 nm, for example.

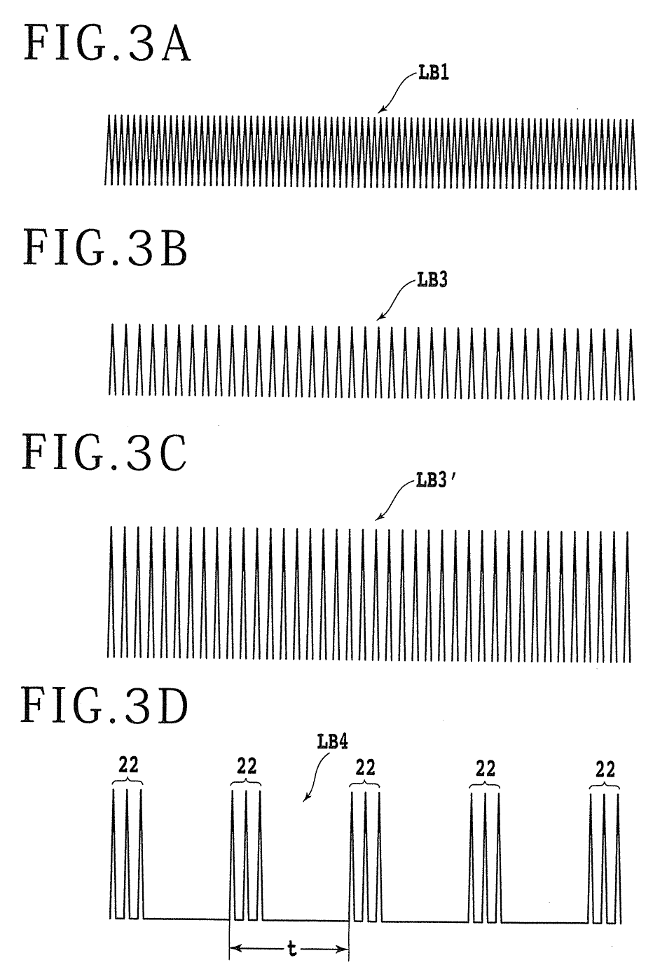

The pulsed laser beam LB1 emitted from the pulsed laser oscillator 2 has a very high repetitive frequency of several tens MHz, for example, as illustrated in FIG. 3A.

The pulsed laser beam LB1 from the pulsed laser oscillator 2 is applied to first thinning-out means 18. The first thinning-out means 18 thins-out pulses of the pulsed laser beam LB1 at predetermined intervals, thereby converting the pulsed laser beam LB1 into a pulsed laser beam LB3 having a repetitive frequency ranging from several MHz to several tens MHz, as illustrated in FIG. 3B. The first thinning-out means 18 may include an acousto-optical modulator (AOM) with a beam shuttering capability, for example.

The pulsed laser beam LB3 emitted from the first thinning-out means 18 is applied to the amplifier 6 that amplifies the pulsed laser beam LB3 into a pulsed laser beam LB3′ as illustrated in FIG. 3C. The pulsed laser beam LB3′ amplified by the amplifier 6 is applied to second thinning-out means 20, which may also include an acousto-optical modulator (AOM) with a beam shuttering capability, for example.

The second thinning-out means 20 thins-out pulses of the pulsed laser beam LB3′ successively and intermittently at predetermined intervals, thereby converting the pulsed laser beam LB3′ into a burst pulsed laser beam LB4 having bursts of pulses 22 as illustrated in FIG. 3D. The burst pulsed laser beam LB4 is emitted from the second thinning-out means 20.

Adjacent ones of the bursts of pulses 22 illustrated in FIG. 3D are spaced from each other by an interval t in the range from 50 to 100 μs. The burst pulsed laser beam LB4 generated by the second thinning-out means 20 is reflected by the mirror 10 of the beam condenser 8 and applied through the condensing lens 12 to the workpiece 11 held on the chuck table 14.

As with the laser beam applying unit 3 according to the first embodiment illustrated in FIG. 1, the laser beam applying unit 7 according to the second embodiment uses a relatively thick workpiece as the plate-shaped workpiece 11. According to the second embodiment, a sheet of glass that is 3 mm thick is used as the workpiece 11.

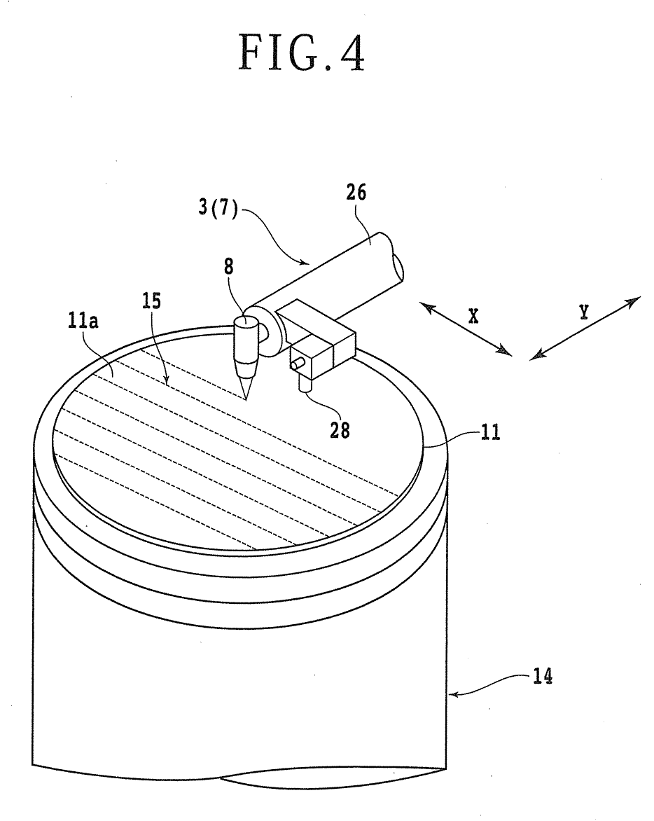

FIG. 4 illustrates in fragmentary perspective a laser processing apparatus suitable for performing the methods of processing a workpiece with a laser beam according to the first and second embodiments of the present invention. As illustrated in FIG. 4, the laser processing apparatus includes the laser beam applying unit 3 or 7 as well as the chuck table 14. The laser beam applying unit 3 or 7 has a housing 26 disposed over the chuck table 14 and housing therein the pulsed laser beam generating unit 5 illustrated in FIG. 1 or the burst pulsed laser beam generating unit 16 illustrated in FIG. 2.

The pulsed laser beam that is emitted from the pulsed laser beam generating unit 5 or the burst pulsed laser beam generating unit 16 is focused inside the workpiece 11 by the beam condenser 8, forming shield tunnels 15, to be described in detail later, in the workpiece 11 along projected dicing lines or streets on the workpiece 11.

The laser processing apparatus includes an image capturing unit 28 having a microscope and a camera for performing an alignment process for focusing the pulsed laser beam with the beam condenser 8. The image capturing unit 28 is mounted on the housing 26 of laser beam applying unit 3 or 7 in alignment with the beam condenser 8 along an X-axis.

For forming shield tunnels 15 in the workpiece 11, the workpiece 11 is held under suction on the chuck table 14 of the laser processing apparatus. Then, the beam condenser 8 applies the pulsed laser beam or the burst pulsed laser beam emitted therefrom to the workpiece 11 to form shield tunnels 15 in the workpiece 11. The chuck table 14 is rotatable about its own vertical central axis and is also movable along the X-axis as well as a Y-axis perpendicular to the X-axis.

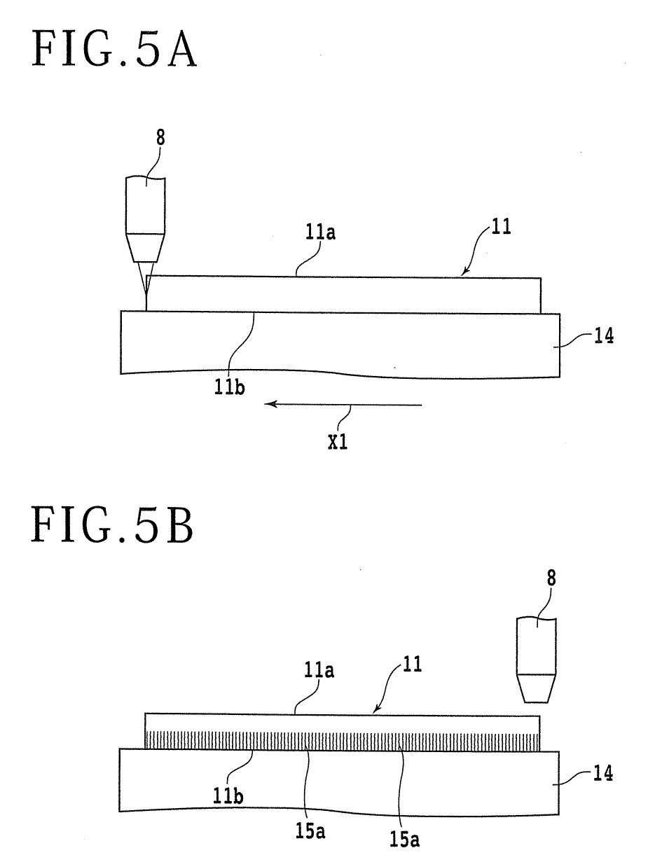

The laser processing methods according to the embodiments of the present invention will be described in detail below with reference to FIGS. 5A through 9C. In the laser processing method according to the first embodiment, as illustrated in FIG. 5A, the pulsed laser beam LB2′ or the burst pulsed laser beam LB4 is converged by the beam condenser 8 within a zone referred to as “converged zone” in the vicinity of a lower surface 11b of the workpiece 11.

The term “converged zone” is used to refer to the zone within which the pulsed laser beam LB2′ or the burst pulsed laser beam LB4 is converged into different focused spots along the optical path of the condensing lens 12 due to the spherical aberration of the condensing lens 12. Therefore, the converged zone extends along thicknesswise directions of the workpiece 11.

As illustrated in FIG. 5A, the pulsed laser beam LB2′ or the burst pulsed laser beam LB4 emitted from the beam condenser 8 is applied to the workpiece 11 while the converged zone thereof is in the vicinity of the lower surface 11b of the workpiece 11. At the same time, the chuck table 14 is processing-fed in the direction indicated by the arrow X1 in FIG. 5A. As a result, as illustrated in FIG. 5B, a plurality of first shield tunnels 15a that extend from the lower surface 11b of the workpiece 11 toward an upper surface 11a thereof are formed in the workpiece 11. The first shield tunnels 15a have lower ends exposed on the lower surface 11b. As disclosed in Japanese Patent No. 6151557, each of the first shield tunnels 15a is made up of fine pores and an amorphous substance surrounding the fine pores. The process of forming shield tunnels in the workpiece 11 will be referred to as “shield tunnel forming step.”

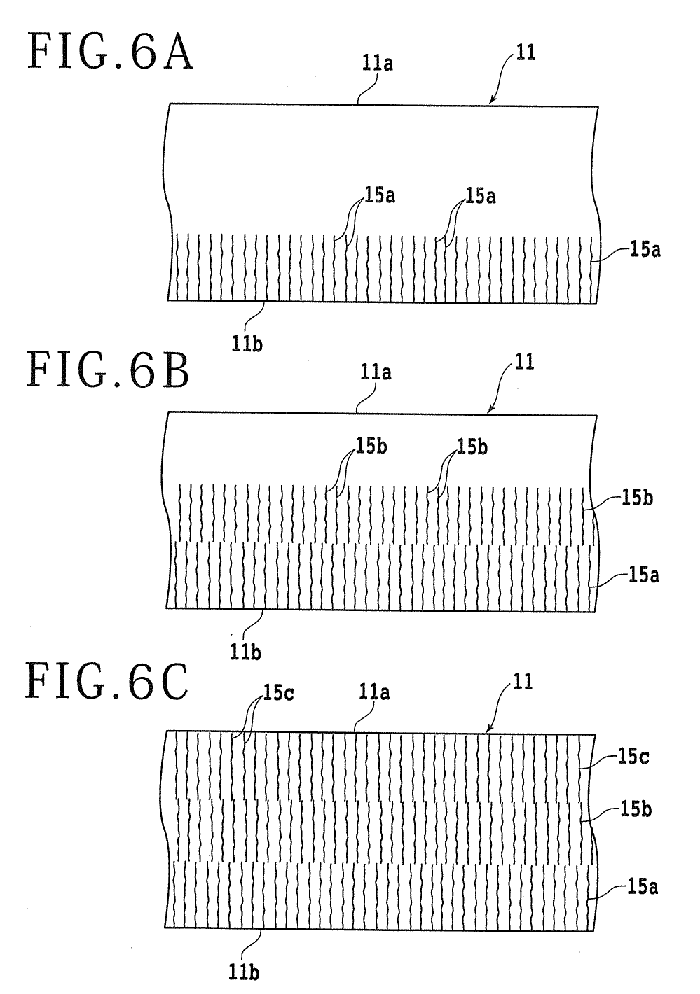

The laser processing method according to the first embodiment will be described in further detail below with reference to FIGS. 6A through 6C. If the workpiece 11 is relatively thin, e.g., if the workpiece 11 is 400 μm or less thick, then it is possible to form shield tunnels 15 in the workpiece 11 that extend from the lower surface 11b up to the upper surface 11a thereof in a single stroke of laser beam scanning in the direction indicated by the arrow X1. However, since the workpiece 11 used in the present embodiment is thicker, the first shield tunnels 15a that can be formed in a single stroke of laser beam scanning extend from the lower surface 11b of the workpiece 11 to a position somewhere along the thicknesswise directions of the workpiece 11.

In the laser processing method according to the first embodiment, the shield tunnel forming step is repeated a plurality of times while the converged zone of the pulsed laser beam LB2′ or the burst pulsed laser beam LB4 is being changed in the thicknesswise directions of the workpiece 11. Further details of the laser processing method according to the first embodiment will be described below with reference to FIGS. 6A through 6C.

FIG. 6A is a schematic fragmentary cross-sectional view of the workpiece 11 after a first shield tunnel forming step according to the first embodiment has been performed thereon. In the first shield tunnel forming step, the pulsed laser beam LB2′ or the burst pulsed laser beam LB4 which has a wavelength transmittable through the workpiece 11 is applied to the workpiece 11 with the converged zone thereof being positioned near the lower surface 11b of the workpiece 11, forming a plurality of first shield tunnels 15a, each made up of fine pores and an amorphous substance surrounding the fine pores, in the workpiece 11 near the lower surface 11b along the projected dicing lines.

After the first shield tunnel forming step has been performed on the workpiece 11, the converged zone of the pulsed laser beam LB2′ or the burst pulsed laser beam LB4 applied by the beam condenser 8 is changed in the thicknesswise directions of the workpiece 11 to a position above the first shield tunnels 15a in a converged zone position changing step.

After the converged zone position changing step has been performed, as illustrated in FIG. 6B, the pulsed laser beam LB2′ or the burst pulsed laser beam LB4 which has a wavelength transmittable through the workpiece 11 is applied to the workpiece 11 with the converged zone thereof being positioned above the first shield tunnels 15a, forming a plurality of second shield tunnels 15b in the workpiece 11 along the direction in which the laser beam is applied, i.e., in the thicknesswise directions of the workpiece 11, in an array adjacent and parallel to the first shield tunnels 15a in a second shield tunnel forming step. The first shield tunnels 15a and the second shield tunnels 15b may not necessarily be aligned with the processing feed direction indicated by the arrow X1.

If the sum of the lengths of the shield tunnels 15a, 15b formed in a stack along the thicknesswise directions of the workpiece 11 in the first shield tunnel forming step and the second shield tunnel forming step is smaller than the thickness of the workpiece 11, i.e., if the upper ends of the second shield tunnels 15b are short of the upper surface 11a of the workpiece 11, then the converged zone position changing step and the second shield tunnel forming step are repeated.

In other words, the converged zone position changing step and the second shield tunnel forming step are repeated until the sum of the lengths of the shield tunnels 15a and 15b formed in a stack along the thicknesswise directions of the workpiece 11 in the first shield tunnel forming step and the second shield tunnel forming step becomes substantially the same as the thickness of the workpiece 11.

According to the present embodiment, as illustrated in FIG. 6C, after the converged zone is changed in the thicknesswise directions of the workpiece 11 to a position above the second shield tunnels 15b in the converged zone position changing step, the second shield tunnel forming step is carried out again to form third shield tunnels 15c in the workpiece 11 over the second shield tunnels 15b and beneath the upper surface 11a.

The first and second shield tunnel forming steps are carried out under the following laser processing conditions, for example:

Workpiece: a sheet of glass having a thickness of 3 mm

Laser oscillator: LD-excited Q-switch Nd:YAG pulse laser

Wavelength: 1030 nm

Repetitive frequency: 10 kHz

Pulse energy: 60 μJ

Pulse duration: 600 fs

Processing feed speed: 100 mm/s

If the pulse laser beam applied to the workpiece 11 is the burst pulse laser beam LB4, then the repetitive frequency of 10 kHz represents the frequency of the bursts of pulses 22, and the repetitive frequency of each of the bursts of pulses 22 is the frequency of the pulsed laser beam LB3 from the first thinning-out means 18 illustrated in FIG. 2, ranging from several MHz to several tens MHz.

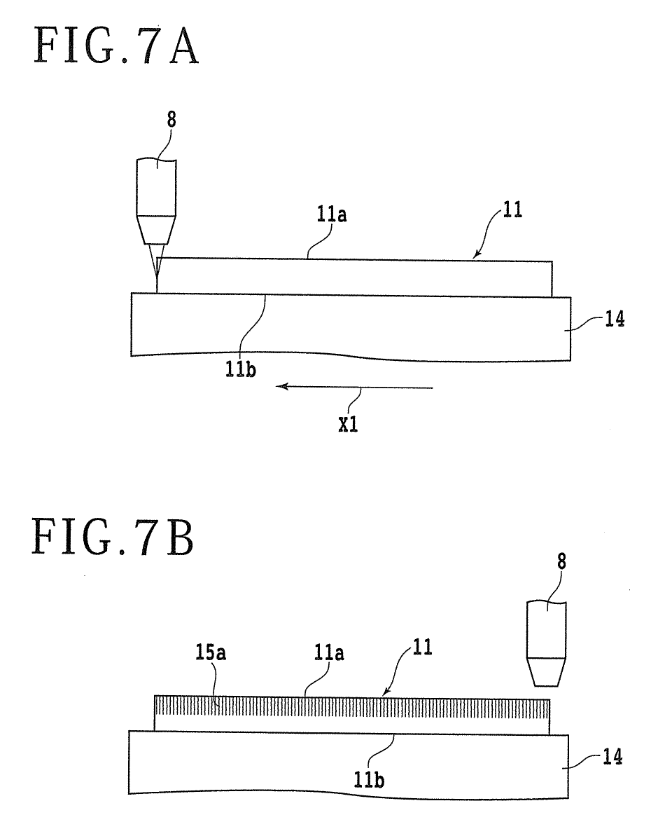

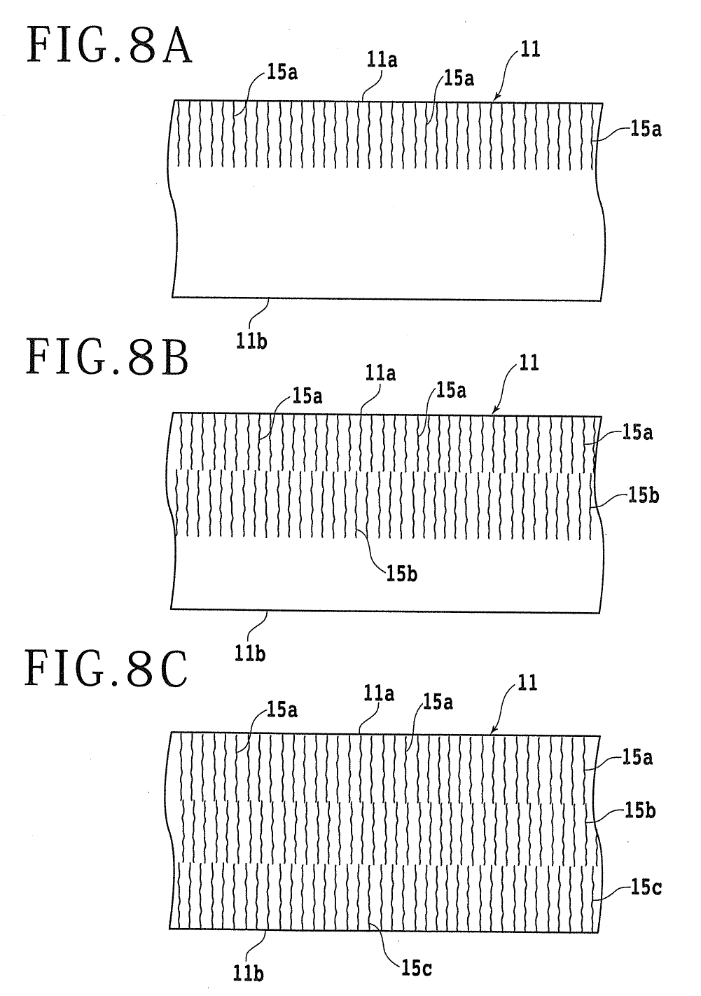

Next, the laser processing method according to the second embodiment will be described below with reference to FIGS. 7A through 8C. In the laser processing method according to the second embodiment, as illustrated in FIG. 7A, the pulsed laser beam LB2′ or the burst pulsed laser beam LB4, which has a wavelength transmittable through the workpiece 11, emitted from the beam condenser 8 is applied to the workpiece 11 while the converged zone thereof is in the vicinity of the upper surface 11a of the workpiece 11. At the same time, the chuck table 14 is processing-fed in the direction indicated by the arrow X1 in FIG. 7A. As a result, as illustrated in FIGS. 7B and 8A, a plurality of first shield tunnels 15a that extend from the upper surface 11a of the workpiece 11 toward the lower surface 11b thereof are formed in the workpiece 11 along the projected dicing lines in a first shield tunnel forming step. The first shield tunnels 15a have upper ends exposed on the upper surface 11a.

Then, the first shield tunnel forming step illustrated in FIG. 8A is followed by a converged zone position changing step and a second shield tunnel forming step that are repeated as illustrated in FIGS. 8B and 8C, in the same manner as with the first embodiment. Specifically, after the first shield tunnel forming step has been performed to form first shield tunnels 15a in the workpiece 11 beneath the upper surface 11a, as illustrated in FIG. 8A, the converged zone position changing step and the second shield tunnel forming step are carried out to form second shield tunnels 15b in the workpiece 11 beneath the first shield tunnels 15a, as illustrated in FIG. 8B. Thereafter, the converged zone position changing step and the second shield tunnel forming step are repeated to form third shield tunnels 15c in the workpiece 11 beneath the second shield tunnels 15b, as illustrated in FIG. 8C.

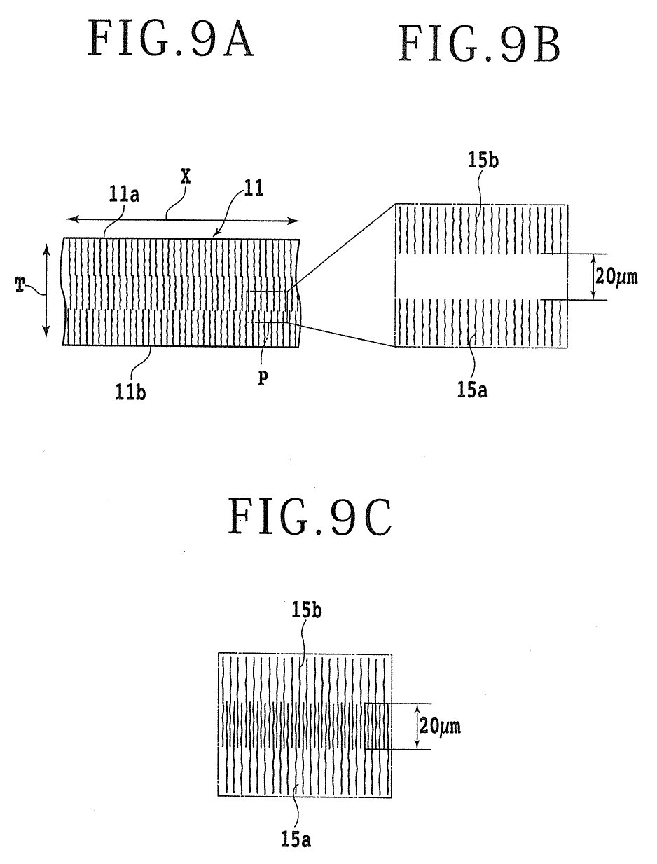

An overlapping relationship between arrays of shield tunnels along the direction in which the laser beam is applied, i.e., in the thicknesswise directions of the workpiece 11, will be described below with reference to FIGS. 9A through 9C. In FIG. 9A, the reference character X represents processing feed directions and the reference character T thicknesswise directions of the workpiece 11. FIG. 9B is an enlarged cross-sectional view of a portion P of the workpiece 11 illustrated in FIG. 9A. In FIG. 9B, the array of first shield tunnels 15a and the array of second shield tunnels 15b are spaced apart from each other by a distance of 20 μm. The state in which the first and second shield tunnels 15a and 15b are spaced apart, i.e., do not overlap each other, is defined as a negatively overlapping state. In the negatively overlapping state illustrated in FIG. 9B, the first and second shield tunnels 15a and 15b may be described as overlapping by a distance of −20 μm. FIG. 9C is an enlarged cross-sectional view of another portion P of the workpiece 11 illustrated in FIG. 9A. In FIG. 9C, the array of first shield tunnels 15a and the array of second shield tunnels 15b overlap each other by a distance of 20 μm.

An experiment was conducted on various workpieces 11 in which the array of first shield tunnels 15a and the array of second shield tunnels 15b overlap each other differently. In the experiment, external forces were applied to the workpieces 11 to cleave or sever the workpieces 11 along the projected dicing lines thereon. As a result, it was found that those workpieces 11 in which the array of first shield tunnels 15a and the array of second shield tunnels 15b overlapped each other along the direction in which the laser beam is applied, i.e., in the thicknesswise directions of the workpieces 11, by distances in the range of ±20 μm exhibited good cleavability, i.e., were severed well.

After the shield tunnels have been formed in the workpiece 11 from the upper surface 11a to the lower surface 11b along the projected dicing lines, a dividing step is carried out to divide the workpiece 11 along the projected dicing lines. The dividing step may be performed by any of various known processes including an etching process, a process of sticking an expandable tape to the workpiece and then expanding the expandable tape to divide the workpiece, a process of breaking the workpiece with a wedge, a process of rolling a roller on the workpiece to divide the workpiece, for example.

For forming shield tunnels in a workpiece with a pulsed laser beam, it is preferable to have the converged zone of the pulsed laser beam extend in the thicknesswise directions of the workpiece. The pulsed laser beam may be either the pulsed laser beam LB2′ illustrated in FIG. 1 or the burst pulsed laser beam LB4 illustrated in FIG. 2 in forming shield tunnels in the workpiece. However, it was experimentally found that workpieces exhibited good cleavability when a burst pulsed laser beam was applied to them.

In the illustrated embodiments, a sheet of glass is used as the workpiece 11. However, the workpiece that can be used in the present invention is not limited to a sheet of glass, but may be any of various workpieces insofar as they have a predetermined thickness or more and are capable of transmitting therethrough a pulsed laser beam having a certain wavelength.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of processing a plate-shaped work-piece with a laser beam so as to be divided along a plurality of projected dicing lines on the workpiece, comprising:
a first shield tunnel forming step of forming a plurality of first shield tunnels, each including fine pores and an amorphous substance surrounding the fine pores, in the workpiece along the projected dicing lines by applying a pulsed laser beam having a wavelength transmittable through the workpiece to the workpiece along the projected dicing lines while positioning a converged zone of the pulsed laser beam within the workpiece;
after the first shield tunnel forming step, a converged zone position changing step of changing a position of the converged zone of the pulsed laser beam to be applied to the workpiece to a position along thicknesswise directions of the workpiece; and
after the converged zone position changing step, a second shield tunnel forming step of forming a plurality of second shield tunnels in the workpiece adjacent and parallel to the first shield tunnels along the direction in which the pulsed laser bream is applied, by applying the pulsed laser beam to the workpiece along the projected dicing lines while positioning the converged zone of the pulsed laser beam within the workpiece, wherein
the converged zone position changing step and the second shield tunnel forming step are repeated until a sum of a length of the first shield tunnels and a length of the second shield tunnels along the thicknesswise directions of the workpiece becomes substantially same as the thickness of the workpiece.

2. The method according to claim 1, wherein the first shield tunnels formed in the workpiece have ends exposed on one of opposite surfaces of the workpiece.

3. The method according to claim 1, wherein the first shield tunnels and the second shield tunnels formed adjacent and parallel to each other in the workpiece along the thicknesswise directions of the workpiece overlap each other along the direction in which the pulsed laser bream is applied, by a distance in a range of ±20 μm.
